(19) United States
(12) Patent Application Publication
(10) Pub. No.: US 2014/0292819 A1
(43) Pub. Date: Oct. 2, 2014

(54) DISPLAY APPARATUS AND IMAGE FORMING METHOD

(71) Applicant: HTC CORPORATION, Taoyuan County (TW)

(72) Inventors: Yu-Wen Lin, Taoyuan County (TW); Hsu-Hsiang Tseng, Taoyuan County (TW); Weng-Chang Shen, Taoyuan County (TW)

(73) Assignee: HTC Corporation, Taoyuan County (TW)

(21) Appl. No.: 13/854,161

(22) Filed: Apr. 1, 2013

(51) Int. Cl. G09G 5/10; H01L 51/52; G02F 1/1335

(52) U.S. Cl. CPC G09G 5/10; G02F 1/1335; H01L 51/52
USPC 345/690; 349/84; 257/40

(57) ABSTRACT

A display apparatus and an image forming method are provided. The display apparatus includes a transparent display layer and a light modification layer. The transparent display layer includes a plurality of pixel units for displaying an image. The light modification layer disposed under the transparent display layer and includes a substrate body having a plurality of first apertures and a plurality of shutter units disposed above the substrate body. When at least one of the shutter units is moved to a first position, an incident light transmits through the shutter unit and is reflected by the substrate body. When at least one of the shutter units is moved to a second position, the incident light transmits through the shutter unit and the at least one of first apertures.

### BACKGROUND OF THE INVENTION

1. Field of the Disclosure

The disclosure generally relates to a display apparatus and an image forming method, and more particularly, to a display apparatus and an image forming method using a shutter unit to switch a background for the display.

2. Description of Related Art

Within the development of the display industry, transparent display panel has become a popular development topic. The transparent display panel is developed to display images without backlights, and the display panel may be a see-through display panel. Therefore, the display panel is also suitable and effective for augmented reality application. Based on the above-mentioned advantages, transparent display panel is commercially appealing.

Thin-Film Transistor Liquid Crystal Display (TFT-LCD) and Organic Light-Emitting Diode Display (OLED display) are two types of the transparent display. Both TFT-LCD and OLED provide good image quality, but each type of the transparent display has its own defect. For TFT-LCD type transparent display, there is no white pixel due to the white pixel is transparent. Relatively, for OLED type transparent display, there is no black pixel due to the black pixel is transparent. Further, due to the transparency of the display panel, contrast and visibility of images are somewhat low for the user. Thereby, how to improve contrast and visibility of images and achieve an optimal image quality for transparent display panel is one of the major subjects in the industry.

### SUMMARY OF THE DISCLOSURE

The disclosure is directed to a display apparatus, in which a shutter unit is employed for switching and providing backgrounds, so as to improve contrast and visibility of images and to achieve an optimal image quality.

The disclosure is also directed to an image forming method, in which a shutter unit is moved to different positions for switching and providing backgrounds, so as to improve contrast and visibility of images and to achieve an optimal image quality.

An embodiment of the disclosure provides a display apparatus. The display play apparatus includes a transparent display layer and a light modification layer. The transparent display layer includes a plurality of pixel units for displaying images. The light modification is disposed under the transparent display layer and includes a substrate body having a plurality of first apertures and a plurality of shutter units disposed above the substrate body. Further, the plurality of the shutter units is between the plurality of the pixel units and the plurality of the first apertures. When at least one of the shutter units is moved to a first position and misaligns with at least one of the first apertures, an incident light transmits through the shutter unit and is reflected by the substrate body. When at least one of the shutter units is moved to a second position and aligns with the at least one of the first aperture, the incident light transmits through the shutter unit and the at least one of the first apertures.

An embodiment of the disclosure provides a method of forming an image on a display apparatus having a transparent display layer and a light modification layer. The transparent display layer includes a plurality of pixel units, and the light modification layer is disposed under the transparent display layer and includes a substrate body having a plurality of first apertures and a plurality of shutter units disposed above the substrate body. The method includes the following steps. At least one of the plurality of pixel units is driven to display images. When the at least one of the plurality of pixel units is driven, at least one of the plurality of the shutter units corresponding to the driven pixel unit is moved to a first position, and an incident light transmits through the shutter unit and is reflected by the substrate body. When at least one of the plurality of pixel units is not driven, at least one of the plurality of shutter units corresponding to the undriven pixel unit is moved to the first position so that the incident light transmits through the shutter unit and is reflected by the substrate body or a second position so that the incident light transmits through the shutter unit and the substrate body.

As described above, in the display apparatus provided by the present disclosure, the shutter units are respectively controlled for adjusting the incident light, and the substrate body can be employed as a background by controlling the shutter unit for the display apparatus while displaying images. Thus, the display apparatus is configured to improve contrast and visibility of images and to achieve an optimal image quality. Moreover, when the display apparatus is disabled, the light modification layer can also be configured to allow the incident light to pass, so as to maintain the transparency of the display apparatus. The method for forming an image provided by the present disclosure using the shutter units for adjusting the incident light as well.

These and other exemplary embodiments, features, aspects, and advantages of the disclosure will be described and become more apparent from the detailed descriptions of exemplary embodiments when read in conjunction with accompanying drawings.

### BRIEF DESCRIPTION OF THE DRAWINGS

The accompanying drawings are included to provide a further understanding of the disclosure, and are incorporated in and constitute a part of this specification.

The drawings illustrate embodiments of the disclosure and, together with the description, serve to explain the principles of the disclosure.

FIG. 1 is an exploded diagram of a display apparatus according to an embodiment of the disclosure.

FIG. 2A is a schematic diagram of moving the shutter unit to a first position according to an embodiment of the disclosure.

FIG. 2B is a schematic diagram of moving the shutter unit to a second position according to an embodiment of the disclosure.

FIGS. 3A and 3B are top views of a shutter unit according to an embodiment of the present disclosure.

FIG. 4 a schematic diagram of a display apparatus according to an embodiment of the present disclosure.

FIG. 5 a schematic diagram of a display apparatus according to another embodiment of the present disclosure.

FIG. 6 is a flowchart of a method of forming an image on a display apparatus.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

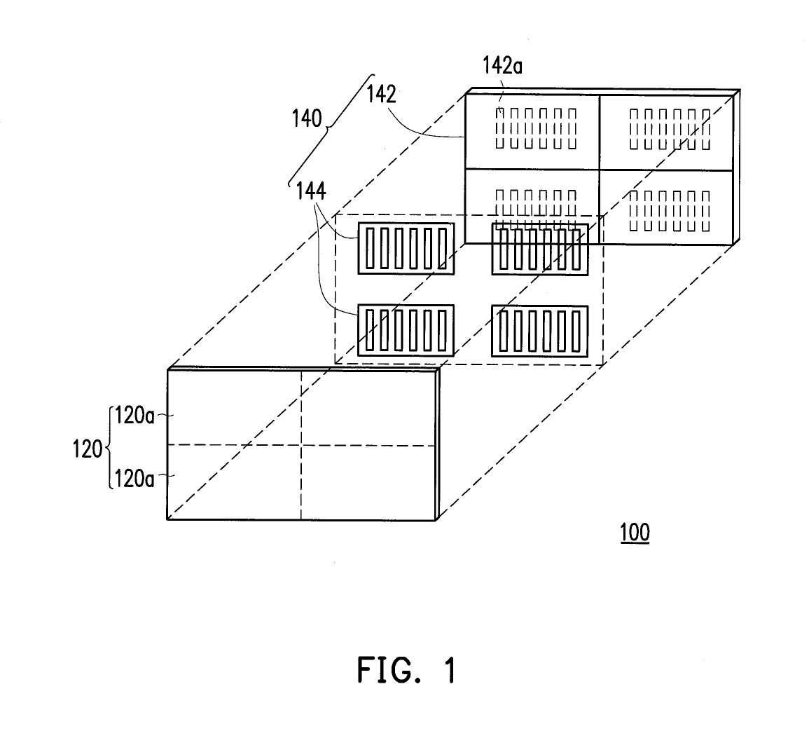

FIG. 1 is an exploded diagram of a display apparatus according to an embodiment of the disclosure. Referring to FIG. 1, the display apparatus 100 includes a transparent display layer 120 and a light modification layer 140. The transparent display layer 120 includes a plurality of pixel units 120a for displaying an image. The light modification layer 140 is disposed under the transparent display layer 120 and includes a substrate body 142 having a plurality of first apertures 142a and a plurality of shutter units 144 disposed above the substrate body 142. The plurality of the shutter units 144 is disposed between the plurality of pixel units 120a and the plurality of the first apertures 142a. In FIG. 1, each of the shutter units 144 is respectively disposed between one pixel unit 120a and at least one of the first apertures 140a. However, in another embodiment, more than one shutter unit can also be disposed between one pixel unit and at least one of the first apertures. Further, in another embodiment, each of the pixel units can include a plurality of sub-pixel units, and each of the sub-pixel units is corresponding to the plurality of shutter units and the plurality of the first apertures.

The shutter units 144 are movable. By respectively controlling and moving the shutter units 144, the incident lights transmitting through the transparent display layer 120 and the shutter units 144 are respectively reflected by the substrate body 142 or respectively transmit through the first apertures 142a. The detailed description of controlling the shutter units 144 is provided with diagrams below.

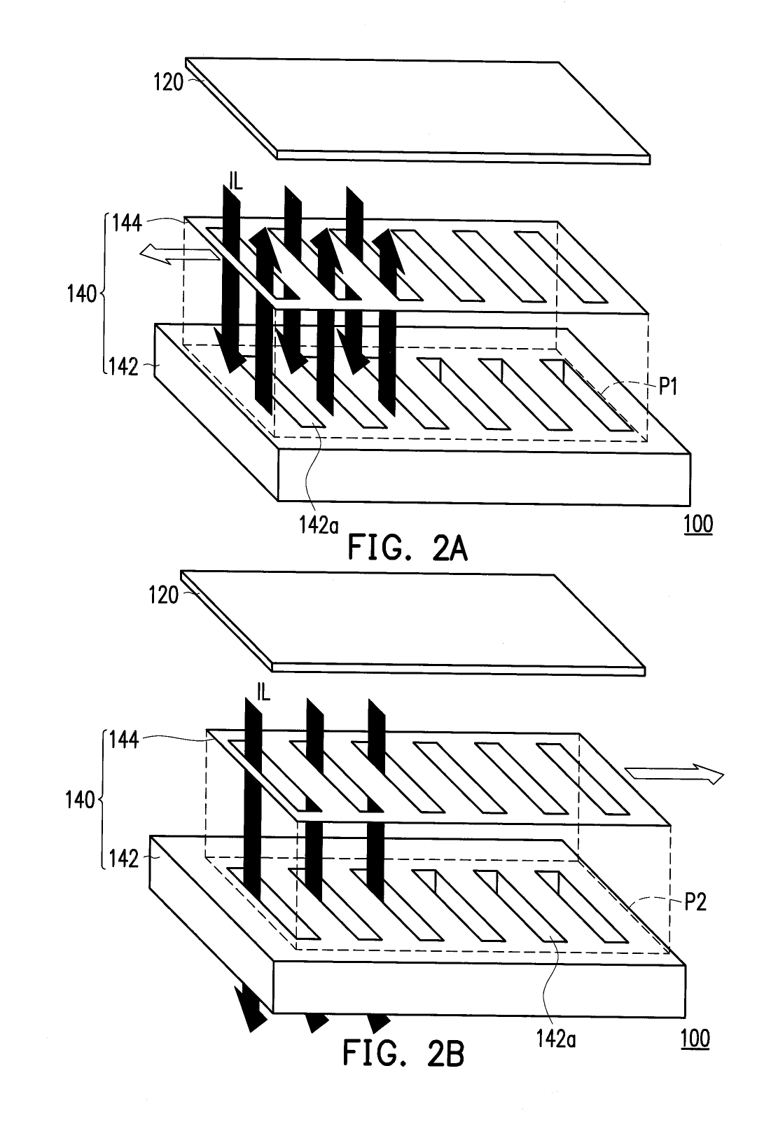

FIG. 2A is a schematic diagram of moving the shutter unit to a first position according to an embodiment of the disclosure. To simplify the diagram, only one shutter unit 144 is shown in the diagram. Referring to FIG. 2A, when at least one of the shutter units 144 is moved to a first position P1 and misaligns with the at least one of the first aperture 142a, the incident light IL transmits through the shutter unit 144 and is reflected by the substrate body 142. To be more specific, only a portion of the shutter unit 144 allows the incident light IL to pass through it. Therefore, when the shutter unit 144 is misaligned with the first apertures 142a, the incident light IL transmitting though the shutter unit 144 is projected to the substrate body 142 and is reflected back to the transparent display layer 120. That is to say, the light modification layer 140 is configured to reflect the incident light IL by the substrate body 142, and the substrate body 142 is employed as a background.

On the other hand, the light modification layer 140 can also be configured to allow the incident light IL to pass. FIG. 2B is a schematic diagram of moving the shutter unit to a second position according to an embodiment of the disclosure. As same as the FIG. 2A, only one shutter unit 144 is shown in FIG. 2B. Referring to FIG. 2B, when the at least one of the shutter units 144 is moved to a second position P2 and aligns with the at least one of the first aperture 142a, the incident light IL transmits through the shutter unit 144 and the at least one of the first apertures 142a. Since the shutter unit 144 is aligned with the at least one of the first apertures 142a, the incident light IL is capable of transmitting through the light modification layer 140. As the result, the pixel unit corresponding to the shutter unit 144 and the first apertures 142a shown in FIG. 2B is regarded as a transparent pixel unit.

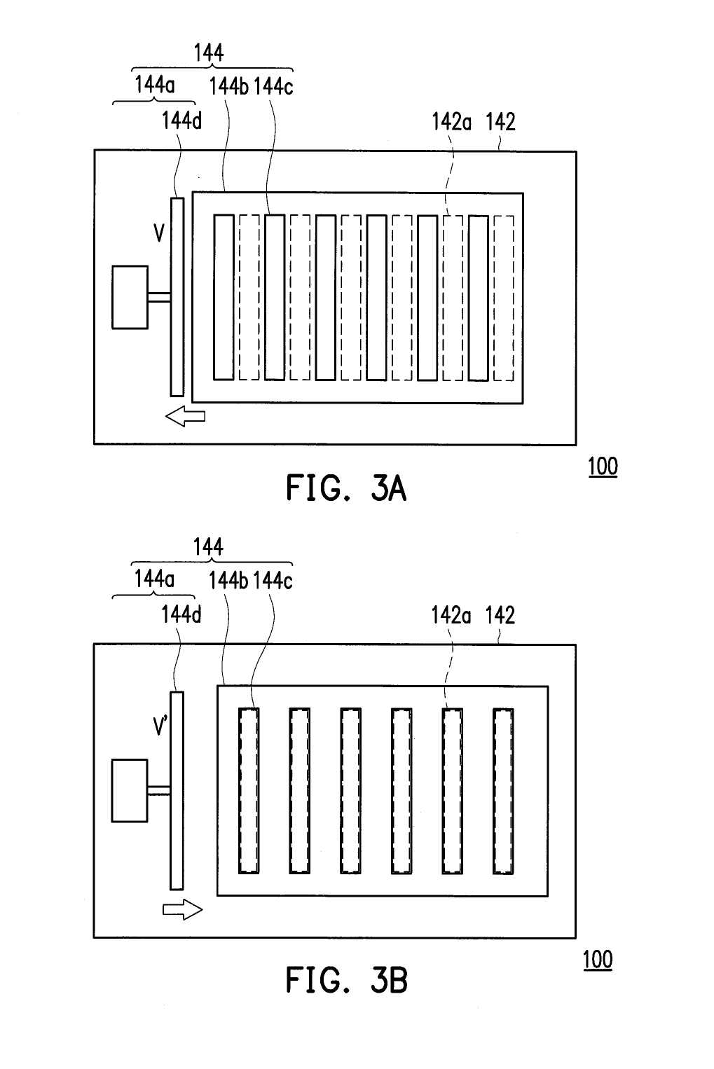

FIGS. 3A and 3B are top views of a shutter unit according to an embodiment of the present disclosure. Referring to FIG. 3A, the shutter unit 144 includes at least one actuator 144a and a shutter 144b having at least one second aperture 144c and coupled to the actuator 144a. The actuator 144a moves the shutter 144b to the first position P1 or the second position P2 transversely over a surface of the substrate body in plane of motion which is parallel to the surface of the substrate body 142 (as shown in FIGS. 2A and 2B). In this embodiment, when the shutter 144b is moved to the second position P2, the second apertures 144c are aligned with the first apertures 142a as shown in FIG. 3B, and the incident light is capable of transmitting through the substrate body 142 through the first aperture 142a and the second aperture 144c. By contrast, when the shutter 144b is moved to the first position P1, the first apertures 144c are misaligned with the second apertures 142a as shown in FIG. 3A, and the incident light transmits through the shutter unit 144 and reaches the substrate body 142.

Referring to FIGS. 3A and 3B, the shutter 144b can be moved towards or away from the actuator 144a by magnetic force or electrostatic force. In the present embodiment, the actuator 144a includes a drive electrode 144d. When an electric potential V is applied to the drive electrode 144d, the shutter 144b is electrostatically drawn towards the drive electrode 144d. According to the present embodiment, when the shutter 144b is drawn towards the actuator 144a, the second apertures 144c are misaligned with the first apertures 142a. That is to say, the shutter 144b is moved to the first position. As the result, the incident light transmitting through the shutter 144b will be reflected by the substrate body 142. Obviously, when an opposite electric potential V′ shown in FIG. 3B is applied to the drive electrode 144d, the shutter 144b is electrostatically moved away from the actuator 144a. Therefore, the second apertures 144c are aligned with the first apertures 142a, and the incident light is capable of transmitting through the shutter unit 144 and the substrate body 142.

The present disclosure is not limited to the embodiment shown above, and the shutter unit 144 can be designed with different patterns. For example, a load electrode (not shown) coupled to the shutter 144b can be disposed between the drive electrode 144d and the shutter 144b. Both of the drive electrode 144d and the load electrode are made by flexible material. When the electric potential V is applied to the drive electrode 144d, the load electrode is thus attracted by the drive electrode 144d, so as to pull the shutter 144b towards the actuator 144a. Further, another actuator (not shown) can be disposed opposite to the actuator 144a. By using more than one actuator, movement of the shutter 144b can be precisely controlled.

In the previous description, the substrate body 142 is adopted as the background while the shutter unit 144 is moved to the first position P 1. However, the present disclosure is not limited herein, and a first layer disposed on the substrate body 142 for light modulation is proposed.

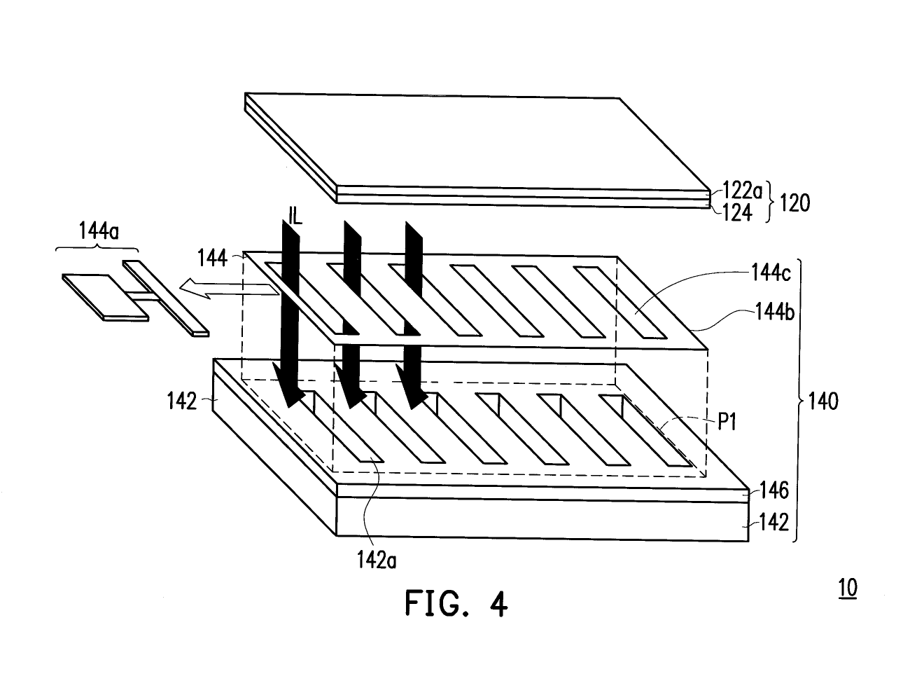

FIG. 4 a schematic diagram of a display apparatus according to an embodiment of the present disclosure. Referring to FIG. 4, the substrate body 142 further includes a first layer 146 disposed on the substrate body 142. In other words, the first layer 146 is disposed between the substrate body 142 and the shutter unit 144. The first layer 146 partially or fully covers the substrate body 142. Further, the transparent display layer 120 includes an organic light emitting diode (OLED) layer 122a and a thin film transistor (TFT) layer 124 configured to drive the OLED layer 122a for displaying images. Both the OLED layer 122a and the TFT layer 124 are transparent. In the present embodiments, when the incident light IL transmits to the first layer 146, the incident light IL is absorbed. By contrast, when the incident light IL is incident on the first apertures 142a, the incident light IL transmits through the substrate body 142. To be more specific, the first layer 146 can be a black color coating layer for light absorbing in this embodiment. The first layer 146 is suitable for use with the OLED layer 122a because the transparent display layer 120 using the OLED layer 122a is lack of black pixels.

To simplify the diagram, only one shutter unit 144 is shown in FIG. 4. When at least one of the pixel units 120a (shown in FIG. 1) is driven for displaying an image, at least one of shutter 144b corresponding to the pixel units 120a is moved to the first position P1 to misalign the second apertures 144c with at least one of first apertures 142a. Therefore, the incident light IL transmitting through the transparent display layer 120 is absorbed by the first layer 146, so as to improve the contrast and the visibility of images. On the other hand, when at least one of the pixel units is not driven and in the idle state, at least one of shutter 144b corresponding to the pixel unit is moved to the second position to align the second apertures 144c of the shutter 144b with at least one of the first apertures 142a. Although FIG. 4 does not illustrate the shutter 144b which is moved to the second position P2, it still can be inferred from FIG. 2B. As the result, the incident light IL is capable of transmitting through the light modification layer 140, so as to maintain the transparency of the pixel units 120a. In other words, the corresponding pixel unit 120a is the transparent pixel. The shutter 144b can be moved by the actuator 144a or other devices in order to reach the effect of the light modulation.

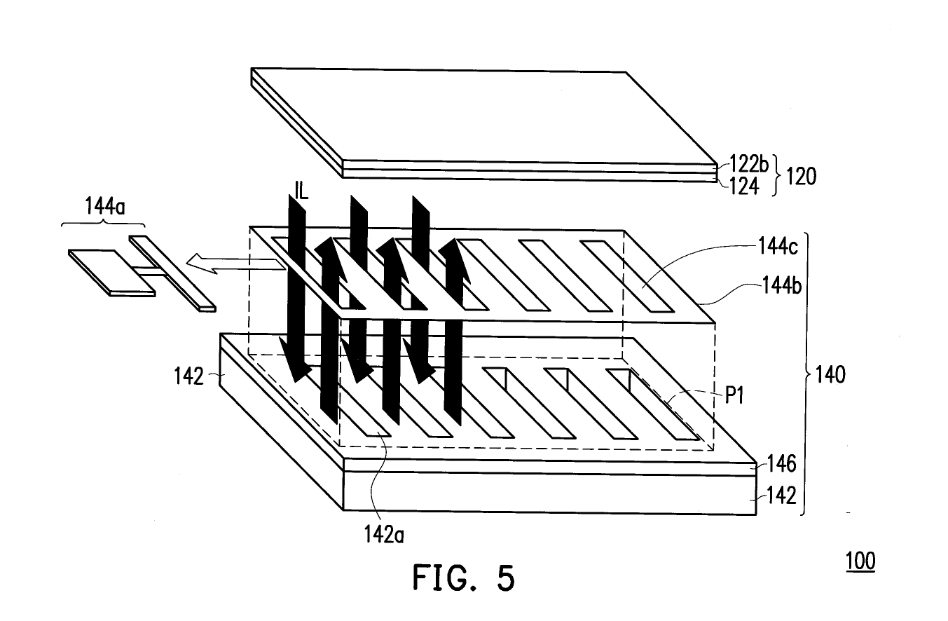

FIG. 5 a schematic diagram of a display apparatus according to another embodiment of the present disclosure. Referring to FIG. 5, the substrate body 142 further includes a first layer 146 disposed on the substrate body 142. The first layer 146 partially or fully covers the substrate body 142. The transparent display layer 120 includes a liquid crystal (LC) layer 122b and a thin film transistor (TFT) layer 124 configured to drive the LC layer 122b for displaying images. Both the LC layer 122b and the TFT layer 124 are transparent. In this embodiment, when the incident light IL transmits to the first layer 146, the incident light IL is reflected by the first layer 146, and when the incident light IL reaches the first apertures 142a, the incident light IL transmits through the substrate body 142. To be more specific, the first layer 146 can be a white color coating layer for light reflecting in this embodiment. The first layer 146 is suitable for use with the LC layer 122b because the transparent display layer 120 using the LC layer 122b and the TFT layer 124 is lack of white pixels.

Similar to FIG. 4, only one shutter unit 144 is shown in FIG. 5. When at least one of the pixel units 120a (shown in FIG. 1) is driven for displaying an image, at least one of the shutters 144b corresponding to the pixel units 120a is moved to the first position P1 to misalign the second apertures 144c with at least one of first apertures 142a. Therefore, the incident light IL transmitting through the transparent display layer 120 is reflected by the first layer 146, so as to improve the contrast and the visibility of images. On the other hand, when at least one of the pixel units is not driven and in the idle state, at least one of shutter 144b corresponding to the pixel unit is moved to the second position to align the second apertures 144c of the shutter 144b with at leak one of the first apertures 142a. Although FIG. 5 does not illustrate the shutter 144b which is moved to the second position P2, it still can be inferred from FIG. 2B. As the result, the incident light IL is capable of transmitting through the light modification layer 140, so as to maintain the transparency of the pixel units 120a.

Based on the above description, the first layer 146 is chosen according to the type of the display using in the transparent display layer 120. However, the first layer 146 can also be chosen for additional function of the display apparatus 100. Referring to the structure of the light modification layer 140 shown in FIGS. 4 and 5 as an example, in one embodiment of the present disclosure, the first layer 146 is a metallic layer. When the incident light IL transmits to the metallic layer, the incident light IL is reflected, and when the incident light IL reaches the first apertures 142a, the incident light IL transmits through the substrate body 142. The display apparatus 100 in this embodiment is further applied as a mirror when the pixel units 120a (shown in FIG. 1) are not driven for displaying images. To be more specific, when at least one of the pixel units 120a is not driven, at least one of the shutters 144b corresponding to the pixel units 120a is moved to the first position P1 to misalign the second apertures 144c of the shutter 144b with at least one of the first apertures 142a. That is to say, when the transparent display layer 120 is in idle state without displaying images, by moving the shutters 144b to the first position P1, the display apparatus 100 can be configured to be a mirror.

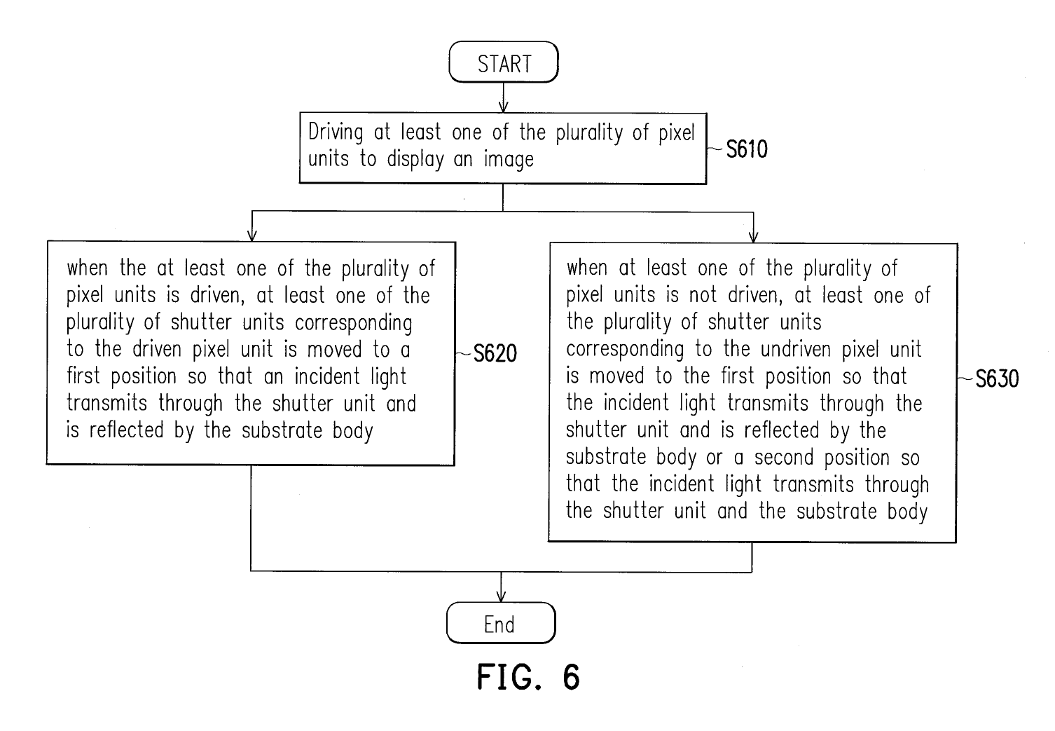

FIG. 6 is a flowchart of a method of forming an image on a display apparatus. In the present disclosure, a method for forming an image on a display apparatus is also provided. The display apparatus includes a plurality of pixel units and a light modification layer disposed under the transparent display layer. The light modification layer further includes a substrate body having a plurality of first apertures and a plurality of shutter units disposed above the substrate body. The method includes the following steps. In step S610, at least one of the plurality of pixel units is driven to display an image. In step S620, when the at least one of the plurality of pixel units is driven, at least one of the plurality of shutter units corresponding to the driven pixel unit is moved to a first position so that the shutter unit misaligns with at least one first aperture, and an incident light transmits through the shutter unit and is reflected by the substrate body. That is to say, the substrate body is used as a back ground for the driven pixel units. However, a portion of the pixel units may be undriven. In step S630, when at least one of the plurality of pixel units is not driven, at least one of the plurality of shutter units corresponding to the undriven pixel is moved to the first position so that the incident light transmits through the shutter unit and is reflected by the substrate body or moved to a second position so that the incident light transmits through the shutter unit and the substrate body. To be more specific, when the shutter unit is moved to the first position, the shutter unit misaligns with at least one of the first apertures, and when the shutter unit is moved to the second position, the shutter unit aligns with the at least one of the first apertures. As the result, the position of the shutter unit is the key for determining whether the incident light transmits through the substrate body.

Based on the above description, when the pixel unit is undriven, the shutter unit is moved to the second position so that the incident light transmits through the shutter unit and the substrate body, so as to maintain the transparency of the pixel unit.

However, the shutter unit can be moved to the first position as well even when the corresponding pixel unit is undriven. Under such condition, all the pixel units are over the same background, so as to bring a consistent visual effect.

As described above, the shutter units are employed by the display apparatus for light modification. To be more specific, the shutter units are respectively moved to the first position or the second position according to the corresponding pixel units. When the shutter unit is moved to the first position, the incident light transmitting through the shutter unit is reflected by the substrate body, and the substrate body is thus applied as the background. Therefore, the contrast and the visibility of images can be improved. By contrast, when the shutter unit is moved to the second position, the incident light transmits through the light modification layer, so as to maintain the transparency of the corresponding pixel unit. Moreover, a first layer disposed on the substrate body can be further applied for various light modification effect. A method for forming an image using the display apparatus described above is also mentioned above.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A display apparatus, comprising:
a transparent display layer comprising a plurality of pixel units for displaying an image; and
a light modification layer, disposed under the transparent display layer and comprising a substrate body, which has a plurality of first apertures, and a plurality of shutter units disposed above the substrate body, and between the plurality of pixel units and the plurality of first apertures, and
wherein when at least one of the shutter units is moved to a first position and misaligns with at least one of the first apertures, an incident light transmits through the shutter unit and is reflected by the substrate body and when the at least one of the shutter units is moved to a second position and aligns with the at least one of the first apertures, the incident light transmits through the shutter unit and the at least one of the first apertures

2. The display apparatus as claimed in claim 1, wherein each of the pixel units comprises a plurality of sub-pixel units.

3. The display apparatus as claimed in claim 1, wherein the shutter unit comprises at least one actuator, and a shutter having at least one second aperture and coupled to the at least one actuator, wherein the at least one actuator moves the shutter to the first position or the second position transversely over a surface of the substrate body in plane of motion which is parallel to the surface of the substrate body.

4. The display apparatus as claimed in claim 3, wherein when the shutter is moved to the second position to align the at least one second aperture with the at least one of first apertures, the incident light transmits through the substrate body through the first aperture and the second aperture.

5. The display apparatus as claimed in claim 3, wherein the actuator comprises a drive electrode and when an electric potential is applied to the drive electrode, the shutter is electrostatically drawn towards the drive electrode.

6. The display apparatus as claimed in claim 5, wherein the substrate body further comprises a first layer disposed on the substrate body and when the incident light transmits to the first layer, the incident light is absorbed and when the incident light is incident on the first aperture, the incident light transmits through the substrate body.

7. The display apparatus as claimed in claim 6, wherein the transparent display layer comprises an organic light emitting diode (OLED) layer; and a thin film transistor (TFT) layer, configured to drive the OLED layer for displaying the images, wherein the OLED layer and the TFT layer are transparent.

8. The display apparatus as claimed in claim 5, wherein the first substrate body further comprises a first layer disposed on the substrate body and when the incident light transmits to the first layer, the incident light is reflected and when the incident light reaches the first aperture, the incident light transmits through the substrate body.

9. The display apparatus as claimed in claim 8, wherein the transparent display layer comprises a liquid crystal (LC) layer; and a thin film transistor (TFT) layer, configured to drive the LC layer for displaying the images, wherein the LC layer and the TFT layer are transparent.

10. The display apparatus as claimed in claim 5, wherein the first layer is a metallic layer and when the incident light transmits to the metallic layer, the incident light is reflected and when the incident light reaches the first aperture, the incident light transmits through the substrate body.

11. The display apparatus as claimed in claim 3, wherein when the shutter is moved to the first position to misalign the at least one of the first apertures with the at least one second aperture, the incident light transmits through the shutter unit and reaches the substrate body.

12. The display apparatus as claimed in claim 3, wherein when at least one of the pixel units is driven for displaying an image, at least one of the shutters corresponding to the pixel unit is moved to the first position to misalign the at least one second aperture of the shutter with the at least one of the first apertures.

13. The display apparatus as claimed in claim 3, wherein when at least one of the pixel units is not driven, at least one of the shutters corresponding to the pixel units is moved to the first position to misalign the at least one second aperture of the shutter with the at least one of the first apertures.

14. The display apparatus as claimed in claim 3, wherein when at least one of the pixel units is not driven, at least one of the shutters corresponding to the pixel units is moved to the second position to align the at least one second aperture of the shutter with the at least one of the first apertures.

15. A method of forming an image on a display apparatus having a transparent display layer comprising a plurality of pixel units and a light modification layer, disposed under the transparent display layer and comprising a substrate body, which has a plurality of first apertures, and a plurality of shutter units disposed above the substrate body, the method comprising:
driving at least one of the plurality of pixel units to display an image;
wherein when the at least one of the plurality of pixel units is driven, at least one of the plurality of shutter units corresponding to the driven pixel unit is moved to a first position, and an incident light transmits through the shutter unit and is reflected by the substrate body; and
wherein when at least one of the plurality of pixel units is not driven, at least one of the plurality of shutter units corresponding to the undriven pixel unit is moved to the first position so that the incident light transmits through the shutter unit and is reflected by the substrate body or a second position so that the incident light transmits through the shutter unit and the substrate body.
